(19) United States
(12) Patent Application Publication
(10) Pub. No.: US 2025/0358574 A1
(43) Pub. Date: Nov. 20, 2025

(54) TRANSDUCER SYSTEM WITH OPEN LOOP CORRECTION OF LOW FREQUENCY ROLL OFF POINT

(71) Applicant: QUALCOMM Incorporated, San Diego, CA (US)

(72) Inventor: Kevin MCLAUGHLIN, Hollis, NH (US)

(21) Appl. No.: 18/669,124

(22) Filed: May 20, 2024

(51) Int. Cl. H04R 19/04; H03M 1/12

(52) U.S. Cl. CPC H04R 19/04; H03M 1/12; H04R 2201/003

(57) ABSTRACT

In some aspects, a system may comprise a transducer configured to generate an analog signal as a function of an incident signal and an open loop correction circuit configured to control or correct a low frequency roll off (LFRO) point, also known as a three decibel (dB) point, of the analog signal generated by the transducer. For example, in some aspects, the open loop correction circuit may receive an input signal that represents the analog signal, wherein the input signal is associated with a first frequency response with a pole at a first frequency, and the open loop correction circuit may apply a transfer function to the input signal to generate an output signal, wherein the output signal is associated with a second frequency response in which the pole is moved to a second frequency. Numerous other aspects are described.

### FIELD OF THE DISCLOSURE

Aspects of the present disclosure generally relate to transducers and, for example, to controlling or correcting a low frequency roll off (LFRO) point, also known as a −3 decibel (dB) point, of a signal generated by a transducer.

### BACKGROUND

Micro-electro-mechanical systems (MEMS) devices are miniature devices that integrate mechanical and electrical components on a single chip. MEMS devices are typically fabricated using semiconductor manufacturing techniques, which makes MEMS devices highly compatible with integrated circuit (IC) technology. MEMS devices can be used in various applications, spanning from automotive sensors and medical devices to consumer electronics and telecommunications. MEMS devices typically include microscale mechanical structures with physical dimensions that may range from several millimeters to less than one micrometer. For example, a MEMS device may include mechanical structures such as beams, membranes, and/or cantilevers that can be actuated or sensed using electrical signals. The miniaturized mechanical components allow MEMS devices to offer advantages such as low power consumption, high sensitivity, and low cost compared to traditional macro-scale counterparts.

### SUMMARY

In some aspects, a system includes a transducer configured to receive an incident signal and to generate an analog signal as a function of the incident signal; and an open loop correction circuit configured to: receive an input signal that represents the analog signal, wherein the input signal is associated with a first frequency response with a pole at a first frequency; and apply a transfer function to the input signal to generate an output signal, wherein the output signal is associated with a second frequency response in which the pole is moved to a second frequency.

In some aspects, the transfer function cancels the pole associated with the first frequency response with a zero and replaces the cancelled pole with a corrected pole to move the pole to the second frequency.

In some aspects, the zero is a function of the first frequency and a sampling frequency, and the corrected pole is a function of the second frequency and the sampling frequency.

In some aspects, the device includes an analog-to-digital converter (ADC) configured to receive the analog signal from the transducer and to convert the analog signal to the input signal that represents the analog signal.

In some aspects, the open loop correction circuit is further configured to remove a direct current offset from the input signal before the transfer function is applied to the input signal.

In some aspects, the first frequency is a low frequency roll off (LFRO) point associated with the transducer.

In some aspects, the second frequency is a programmed value.

In some aspects, the first frequency is within a first range, and the second frequency is within a second range that is narrower than the first range and overlapping with the first range.

In some aspects, the transducer is a micro-electro-mechanical systems (MEMS) acoustic transducer.

In some aspects, a method includes generating, by a transducer, an analog signal as a function of an incident signal; receiving, by an open loop correction circuit, an input signal that represents the analog signal, wherein the input signal is associated with a first frequency response with a pole at a first frequency; and applying, by the open loop correction circuit, a transfer function to the input signal to generate an output signal, wherein the output signal is associated with a second frequency response in which the pole is moved to a second frequency.

In some aspects, applying the transfer function includes: cancelling the pole associated with the first frequency response with a zero; and replacing the cancelled pole with a corrected pole that moves the pole to the second frequency.

In some aspects, the zero is a function of the first frequency and a sampling frequency, and the corrected pole is a function of the second frequency and the sampling frequency.

In some aspects, the method includes: receiving, by an ADC, the analog signal from the transducer; and converting, by the ADC converter, the analog signal to the input signal that represents the analog signal.

In some aspects, the method includes removing a direct current offset from the input signal before applying the transfer function to the input signal.

In some aspects, the first frequency is an LFRO point associated with the transducer.

In some aspects, the second frequency is a programmed value.

In some aspects, the first frequency is within a first range, and the second frequency is within a second range that is narrower than the first range and overlapping with the first range.

In some aspects, the transducer is a MEMS acoustic transducer.

In some aspects, an apparatus includes means for generating an analog signal as a function of an incident signal; means for generating an input signal that represents the analog signal, wherein the input signal is associated with a first frequency response with a pole at a first frequency; and means for applying a transfer function to the input signal to generate an output signal, wherein the output signal is associated with a second frequency response in which the pole is moved to a second frequency.

In some aspects, the apparatus includes means for removing a direct current offset from the input signal before the transfer function is applied to the input signal.

Aspects generally include a method, apparatus, system, computer program product, non-transitory computer-readable medium, user device, user equipment, wireless communication device, and/or processing system as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example micro-electro-mechanical systems (MEMS) device, in accordance with the present disclosure.

FIGS. 2A-2B are diagrams illustrating an example plan view and an example cross-sectional view of a MEMS device die, in accordance with the present disclosure.

FIGS. 3A-3B are diagrams illustrating examples of variations in frequency responses for different MEMS devices, in accordance with the present disclosure.

FIGS. 4A-4F are diagrams illustrating examples associated with controlling or correcting a low frequency roll off (LFRO) point of a signal generated by a transducer, such as a MEMS acoustic transducer, in accordance with the present disclosure.

FIG. 5 is a flowchart illustrating an example process associated with controlling or correcting an LFRO point of a signal generated by a transducer, such as a MEMS acoustic transducer, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

As described herein, a transducer is a device that converts an incident signal (e.g., energy in a first form) to an output signal (e.g., energy in a second form) such that desired characteristics associated with the incident signal (or input energy) can be read via the output signal. For example, a micro-electro-mechanical system (MEMS) acoustic transducer/sensor may convert an incident signal in the form of acoustic energy into an electrical signal, and/or may convert an electrical signal into acoustic energy. For example, a MEMS acoustic transducer may be a MEMS microphone that can convert sound pressure into an electrical voltage. Based on the transduction mechanisms, MEMS microphones can be made in various forms, such as capacitive microphones or piezoelectric microphones. Although MEMS capacitive microphones and electret condenser microphones (ECMs) are prevalent in consumer electronics, piezoelectric MEMS microphones occupy a growing portion of the consumer market and offer various advantages compared to ECMs and MEMS capacitive microphones. For example, piezoelectric MEMS microphones do not have a back plate, which eliminates squeeze film damping that is an intrinsic noise source for capacitive MEMS microphones. In addition, piezoelectric MEMS microphones are reflow-compatible and can be mounted to a printed circuit board (PCB) using typical lead-free solder processing, which could irreparably damage a typical ECM. However, despite careful fabrication techniques, certain parameters of a MEMS device are difficult to control.

For example, a MEMS microphone has a low frequency roll off (LFRO) point, where a MEMS microphone has a low frequency response that resembles a high pass filter response with a single pole at an LFRO frequency. The LFRO point is typically three decibels (dB) below full scale at a frequency of 25 Hertz (Hz), and is therefore also known as a −3 dB point. However, when piezoelectric MEMS microphones or other MEMS devices are manufactured, the LFRO or −3 dB point can vary widely (e.g., from 20 Hz to 200 Hz), even on the same wafer. For example, during a MEMS device manufacturing process, process variations can occur that may impact performance, such as the frequency response or LFRO point for different MEMS transducers. For example, the process variations may include variations in material properties due to fluctuations in deposition or doping processes, mask alignment errors that lead to deviations in the dimensions and/or shapes of MEMS structures, etch rate variations that lead to non-uniform etching and dimensional inaccuracies, and/or temperature or pressure variations that can affect chemical reaction rates and/or material deposition rates, among other examples. Accordingly, the variations in the LFRO point may prevent MEMS devices from being used in applications that require a specific LFRO (e.g., a MEMS microphone that requires an LFRO point at 25 Hz) or uniformity in an LFRO due to high yield loss, where many MEMS devices are unusable due to having an LFRO point that deviates from the required LFRO.

Some aspects described herein relate to a circuit that may correct or otherwise control an LFRO point or −3 dB point associated with a signal generated by a transducer, such as a MEMS microphone or another MEMS device. For example, as described herein, a transducer such as a MEMS device may be configured to convert an incident signal such as acoustic energy into an electrical signal (e.g., an analog electrical signal) associated with an LFRO point that may depend on one or more variables, such as process variations that may occur when the transducer is manufactured. Accordingly, in some aspects, an open loop correction circuit may be configured to receive an input signal (e.g., a digital signal) representing the electrical signal generated by the transducer, and the open loop correction circuit may correct or otherwise modify the frequency response associated with the input signal such that an output from the open loop correction circuit always has an LFRO response or −3 dB point at a desired frequency (e.g., 25 Hz or another programmed frequency). For example, the transducer may have a high pass filter response with a pole at a first frequency (e.g., the LFRO point or −3 dB corner, which may be measured after manufacturing and/or during production testing of the transducer), and the open loop correction circuit may apply a transfer function to move the pole to a second frequency (e.g., the desired LFRO point). In this way, a transducer may be used in any suitable application that requires a specific LFRO regardless of the intrinsic LFRO point of the transducer, which improves a manufacturing yield. Furthermore, in some aspects, the open loop correction circuit may correct the LFRO point of the transducer in a digital domain, which may use less silicon area and/or provide a more accurate LFRO correction relative to an analog implementation of the open loop correction circuit.

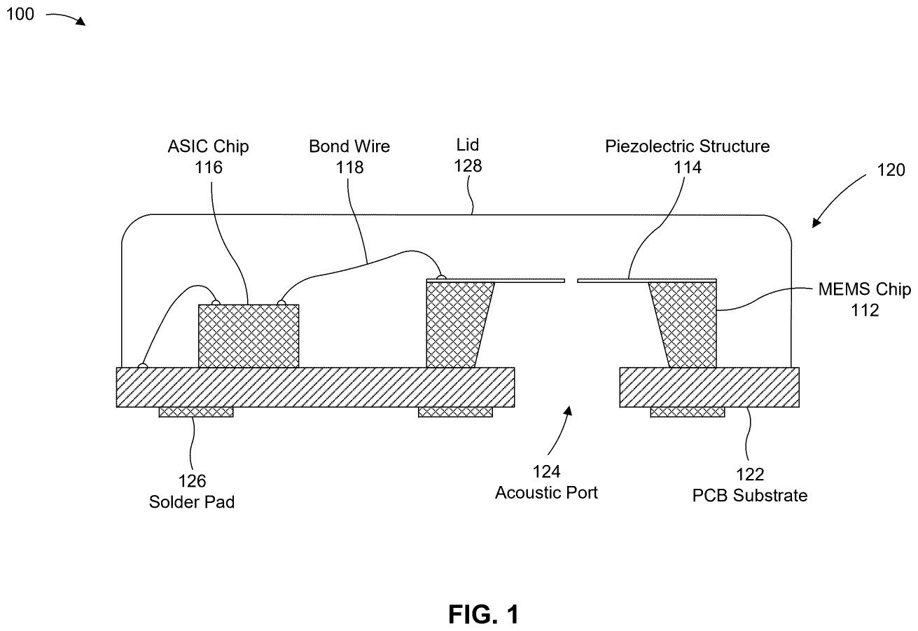

FIG. 1 is a diagram illustrating an example MEMS device 100, in accordance with the present disclosure. In some aspects, the MEMS device 100 is an acoustic sensor or acoustic transducer implemented as a piezoelectric MEMS microphone, which is shown in a cross-sectional view in FIG. 1. As shown in FIG. 1, the MEMS device 100 may include a MEMS chip 112 having one or more piezoelectric structures 114 (e.g., cantilevers or diaphragms) configured to convert sound pressure into an electrical signal, and an application-specific integrated circuit (ASIC) chip 116 configured to buffer and amplify the electrical signal generated by the MEMS chip 112. As further shown in FIG. 1, the MEMS chip 112 and the ASIC chip 116 may be electrically connected by a bond wire 118, and may be mounted within an interior chamber of a package 120. For example, as shown in FIG. 1, the package 120 may include a substrate 122 (e.g., a printed circuit board (PCB) substrate) that forms an acoustic port 124 through which sound pressure may reach the MEMS chip 112. In addition, as further shown, the package 120 may include one or more solder pads 126 that may be used to solder or otherwise attach the package 120 to a board. In some aspects, as shown in FIG. 1, the MEMS device 100 may include a metal lid 128 to form a housing for the MEMS device 100 and to mitigate electromagnetic interference (EMI).

In some aspects, as described herein, the MEMS chip 112 may be formed from or may include one or more piezoelectric structures 114, such as one or more piezoelectric cantilevers and/or diaphragms. For example, in some aspects, the piezoelectric structures 114 may include cantilever structures that are typically stress-free after a die is released during fabrication. On the other hand, diaphragm structures typically require more stress control in the fabrication process, as minimal residual stress within a diaphragm structure can result in significant sensitivity degradation. In some aspects, the piezoelectric structures 114 may include multiple cantilevers arranged to form a piezoelectric sensing structure (e.g., in a square shape, a hexagonal shape, an octagonal shape, or another suitable shape). Furthermore, although the MEMS chip 112 and the ASIC chip 116 are shown as separate chips in FIG. 1, the MEMS chip and the ASIC chip 116 may be implemented on the same die.

As indicated above, FIG. 1 is provided as an example. Other examples may differ from what is described with respect to FIG. 1.

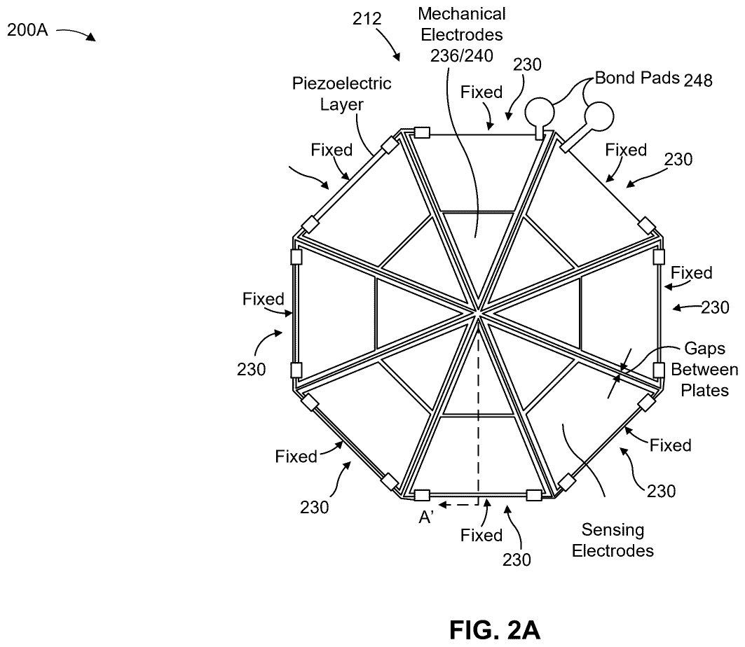

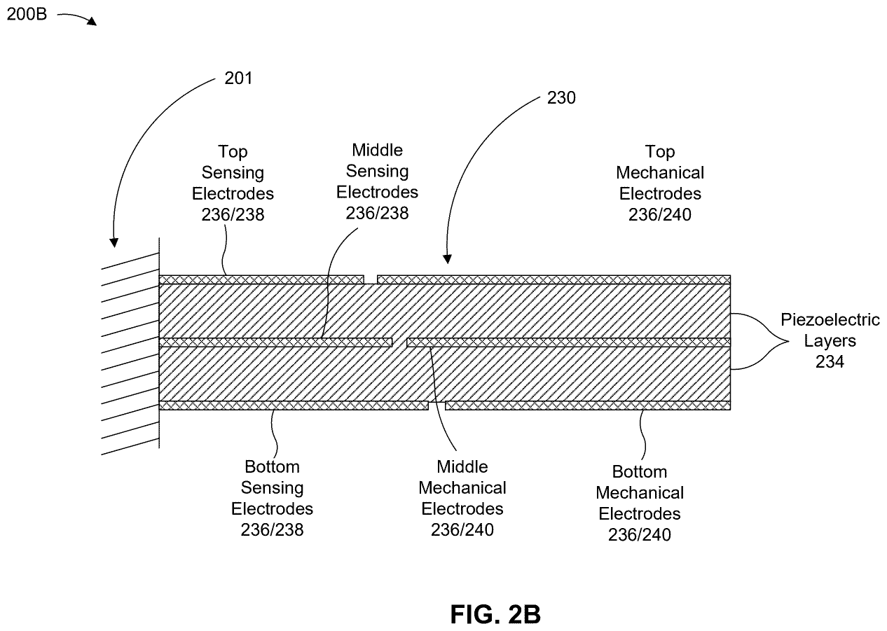

FIGS. 2A-2B are diagrams illustrating an example plan view 200A and an example cross-sectional view 200B of a MEMS device die, in accordance with the present disclosure. As shown in FIG. 2A, the MEMS device die may include a microphone chip 212 having eight sense members (also known as sense arms) formed as piezoelectric cantilevers 230, although more or fewer cantilevers 230 may be used. In the examples shown in FIGS. 2A-2B, the piezoelectric cantilevers 230 each have a triangular shape, and collectively form an octagonal MEMS acoustic sensor.

Referring to FIG. 2B, the cross-sectional view 200B depicts one piezoelectric cantilever 230. As shown in FIG. 2B, the cantilevers 230 may be fixed to a substrate 210 (e.g., a silicon substrate) at respective bases, and the cantilevers 230 may be configured to move freely in response to incoming or incident sound pressure (e.g., an acoustic wave). As described herein, the cantilevers 230 may have a triangular shape, because the triangular shape provides a gap-controlling geometry. For example, when the cantilevers 230 bend up or down (e.g., due to sound pressure or residual stress), gaps between plates associated with adjacent cantilevers 230 (e.g., as shown in FIG. 2A) may remain relatively small.

In some aspects, as shown in FIG. 2B, the cantilevers 230 may be fabricated using one or more piezoelectric layers 234, which may be disposed between top and bottom metal electrodes 236. In some aspects, the piezoelectric layers 234 can be made from any suitable piezoelectric material, such as aluminum nitride (AlN), aluminum scandium nitride (AlScN), zinc oxide (ZnO), and/or lead zirconate titanate (PZT), among other examples. In some aspects, as shown in FIGS. 2A-2B, the electrodes 236 can include sensing electrodes 238 and/or mechanical electrodes 240, which may be made from any suitable metal material, such as molybdenum (Mo), platinum (Pt), nickel (Ni), and/or aluminum (Al), among other examples. Additionally, or alternatively, the electrodes 236 can be formed from a non-metal material, such as doped polysilicon (poly-Si). In some aspects, the electrodes 236 may cover only a portion of the cantilever 230 (e.g., from the base to about one third of the cantilever 230, as these areas generate electrical energy more efficiently within the piezoelectric layers 234 than the areas near the free end). For example, incoming sound pressure may induce high stress concentration in the areas near the base, which may be converted into an electrical signal by a direct piezoelectric effect.

In some aspects, as described herein, the electrodes 236 may include sensing electrodes 238 that may be electrically connected in series to achieve desired capacitance and sensitivity values. In addition to the sensing electrodes 238, the cantilevers 230 may be covered by the top and bottom mechanical electrodes 240 to maintain a mechanical strength of the structure, and the mechanical electrodes 240 do not contribute to the electrical signal generated by the MEMS acoustic sensor.

As indicated above, FIGS. 2A-2B are provided as examples. Other examples may differ from what is described with respect to FIGS. 2A-2B.

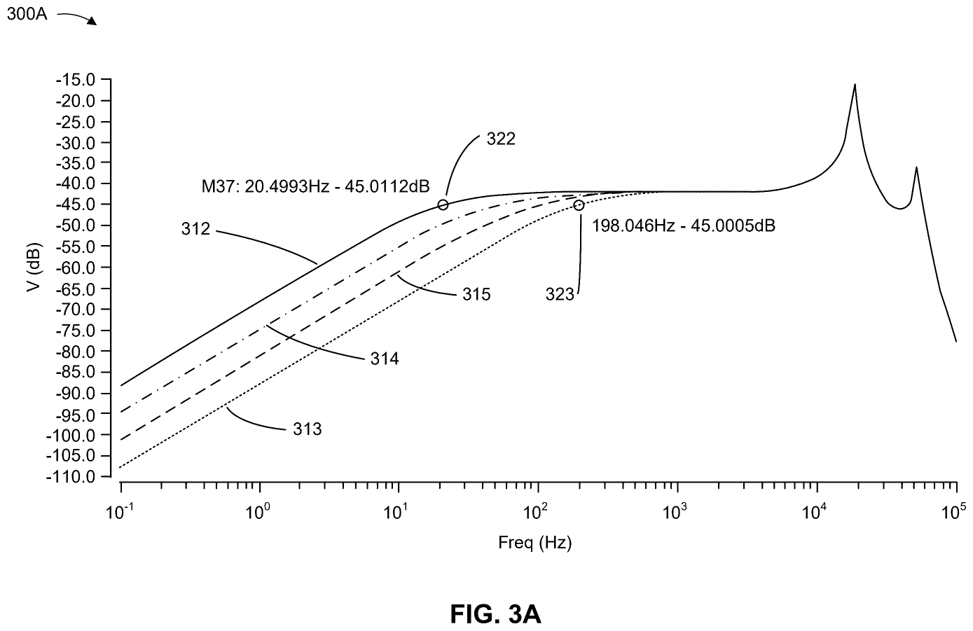

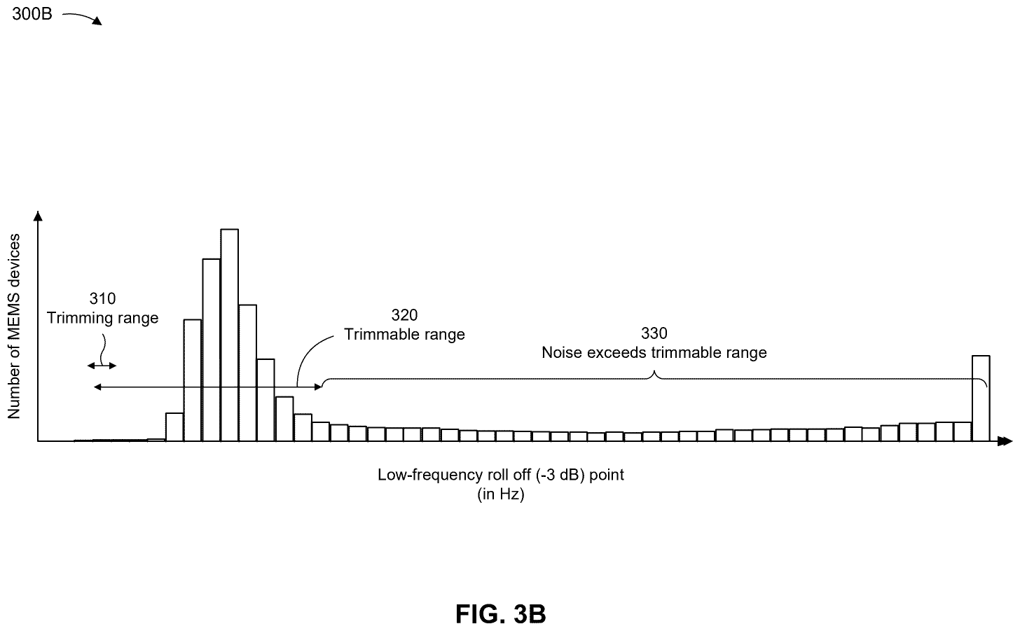

FIGS. 3A-3B are diagrams illustrating examples 300A, 300B of variations in frequency responses for different MEMS devices, in accordance with the present disclosure. For example, examples 300A, 300B relate to variations in frequency responses for different MEMS microphones, such as the MEMS device 100 shown in FIG. 1 and/or the MEMS device die shown in FIGS. 2A-2B, although other transducers may also exhibit variations in frequency responses. For example, in some aspects, there may be variations in frequency responses across different inertial sensors, such as accelerometers and/or gyroscopes, pressure sensors, tilt sensors, speakers, chemical sensors, ultrasonic transducers, and/or condenser and/or capacitive microphones.

Referring to FIG. 3A, example 300A illustrates a respective frequency response for each of 4 transducers. For example, each transducer may be a MEMS microphone or another suitable MEMS device. Furthermore, although example 300A illustrates respective frequency responses for only 4 transducers for simplicity and clarity, a manufacturing process may produce a large number of transducers (e.g., several hundreds or thousands) that each have a respective frequency response that may depend on one or more variables, such as process variations that occur during manufacturing.

As shown in FIG. 3A, a first transducer may have a frequency response illustrated by curve 312, a second transducer may have a frequency response illustrated by curve 313, a third transducer may have a frequency response illustrated by curve 314, and a fourth transducer may have a frequency response illustrated by curve 315. As shown by curves 312-315, each transducer has an LFRO point, where a low frequency response resembles a high pass filter response with a single pole at an LFRO frequency. As described herein, the LFRO point is typically 3 dB below full scale at a desired frequency, and is therefore also known as a −3 dB point. However, when piezoelectric MEMS microphones or other transducers are manufactured, the LFRO or −3 dB point can vary widely, even for devices made on the same wafer. For example, during a MEMS device manufacturing process, the frequency response or LFRO point for different MEMS transducers may vary due to fluctuations in deposition or doping processes, mask alignment errors, etch rate variations, and/or temperature or pressure variations, among other examples. For example, in FIG. 3A, the first transducer has an LFRO point 322 at 20.4993 Hz, where the first transducer produces an output with a voltage amplitude of −45.0012 dB at the LFRO point 322. As another example, the second transducer has an LFRO point 323 at 198.046 Hz, and the other transducers also each have a respective LFRO point (e.g., where the transducer has steadily less capacity to output energy at frequencies below the LFRO point). As shown in FIG. 3A, the frequency responses of the various transducers may deviate from one another, particularly at lower frequencies (e.g., below 1000 Hz), with the deviation being more pronounced at lower frequencies. For example, in FIG. 3A, the LFRO point for different MEMS microphones may vary in a range from about 20 Hz to 200 Hz.

In some cases, the differences in frequency responses across different transducers may be undesirable or unacceptable. For example, a mobile phone manufacturer may desire that each microphone used in a mobile phone has a substantially similar frequency response in order to promote uniformity. As another example, a device may employ two or more transducers, and a manufacturer may desire that each transducer used in the device has a substantially similar frequency response. Additionally, or alternatively, certain microphone applications may require a specific LFRO point, such as 25 Hz. Accordingly, the variations in the LFRO point may prevent MEMS devices or other transducers from being used in certain applications due to a high yield loss (e.g., where many manufactured transducers are unusable for the application due to having an LFRO point that deviates from the required LFRO point).

Accordingly, some aspects described herein relate to a circuit that may correct or otherwise control an LFRO point or −3 dB point associated with a signal generated by a transducer, such as a MEMS microphone or another MEMS device. For example, as described herein, a transducer such as a MEMS device may be configured to convert an incident signal such as acoustic energy into an electrical signal (e.g., an analog electrical signal) associated with an LFRO point that may depend on one or more variables, such as process variations that may occur when the transducer is manufactured. Accordingly, in some aspects, an open loop correction circuit may receive an input signal (e.g., a digital signal) representing the electrical signal generated by the transducer, and may correct or otherwise modify the frequency response associated with the input signal such that an output from the open loop correction circuit always has an LFRO response or −3 dB point at a desired frequency. For example, the transducer may have a high pass filter response with a pole at a first frequency (e.g., the LFRO point or −3 dB corner, which may be measured after manufacturing and/or during production testing), and the open loop correction circuit may apply a transfer function to move the pole to the desired LFRO point.

For example, in FIG. 3B, the horizontal axis represents LFRO points that are measured for various transducers after manufacturing and/or during production testing, and the vertical axis represents a number of transducers. Accordingly, each bar in FIG. 3B has a height that corresponds to a number of transducers that have a measured LFRO point within a particular range. As described herein, the open loop correction circuit may be configured to have a trimming range 310, which corresponds to a range for the LFRO response at the output from the open loop correction circuit, and a trimmable range 320 may correspond to a range of LFRO points that can be corrected via the open loop correction circuit. For example, in some aspects, the trimming range 310 may include frequencies in a range from 20-40 Hz, +10 Hz, and the trimmable range 320 may include frequencies in a range from 25-200 Hz (although other suitable frequencies may be used for the trimming range 310 and/or the trimmable range 320). In general, as shown in FIG. 3B, the trimmable range 320 may include frequencies up to a maximum value, and with frequencies 330 that exceed the maximum value being too noisy to be corrected via the open loop correction circuit. Accordingly, as described herein, the open loop correction circuit may be configured to trim LFRO points in the trimmable range 320 down to the trimming range 310 with a suitable step size (e.g., trimming the 25-200 Hz range down to 20-40 Hz in 5 Hz steps, such that an output from a transducer associated with an LFRO point anywhere in the range between 25-200 Hz can be corrected to have an LFRO of 20, 25, 30, 35, or 40 Hz). In this way, a transducer may be used in any suitable application that requires a specific LFRO regardless of the intrinsic LFRO point of the transducer, which improves a manufacturing yield. Furthermore, as described herein, the open loop correction circuit may correct the LFRO point of the transducer in a digital domain, which may use less silicon area and/or provide a more accurate LFRO correction relative to an implementation of the open loop correction circuit that uses analog circuitry.

As indicated above, FIGS. 3A-3B are provided as examples. Other examples may differ from what is described with respect to FIGS. 3A-3B.

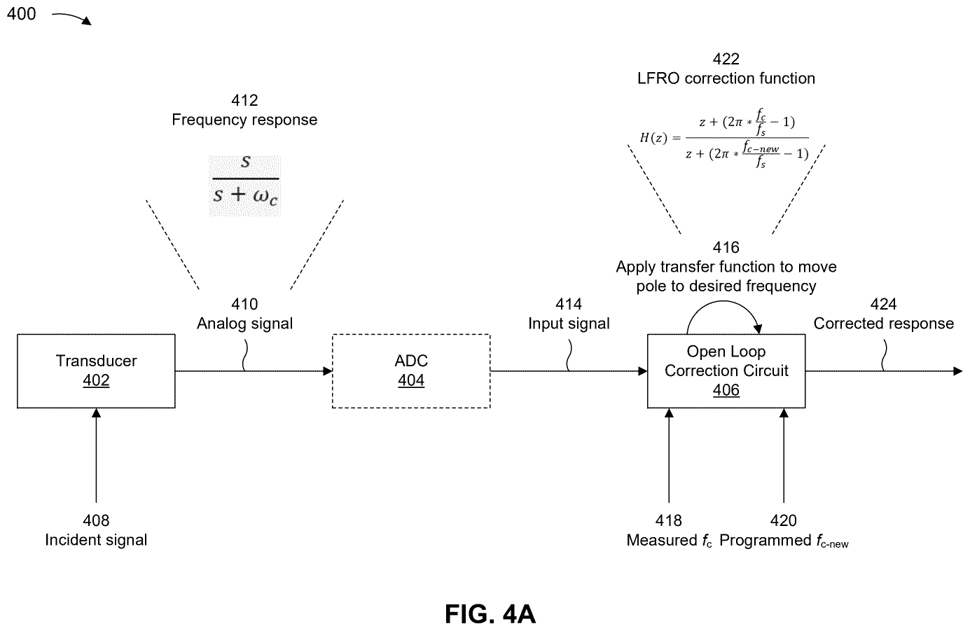

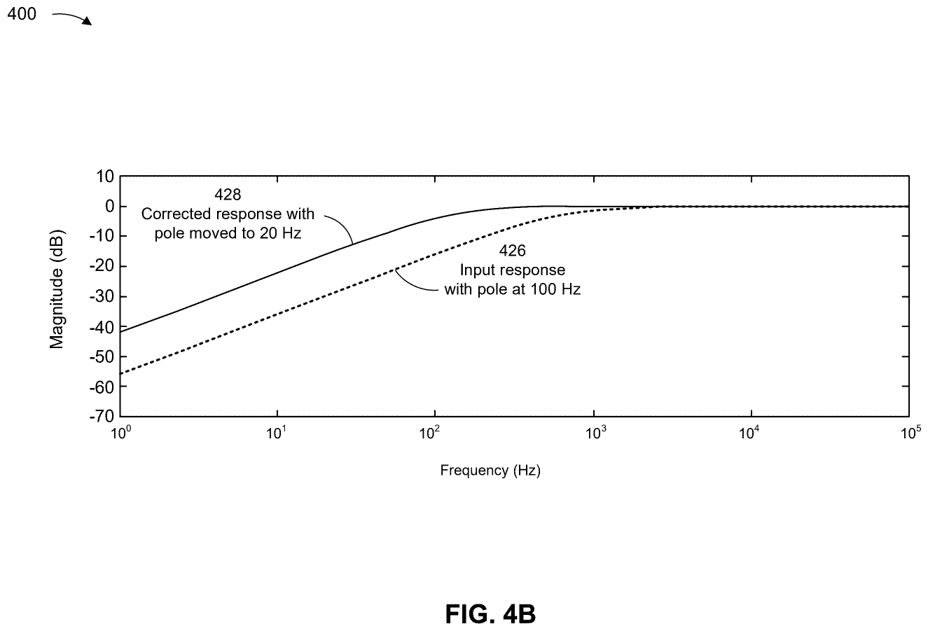

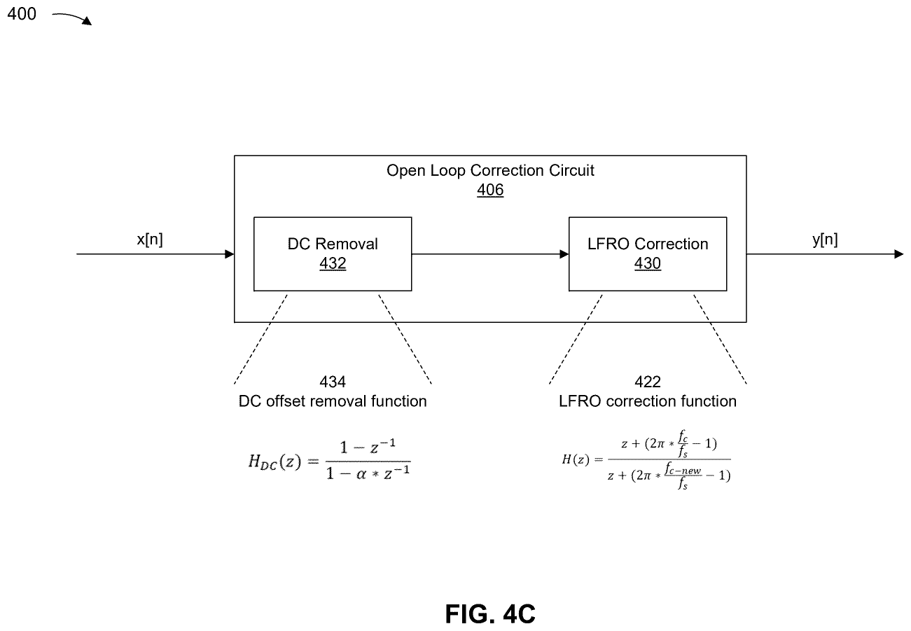

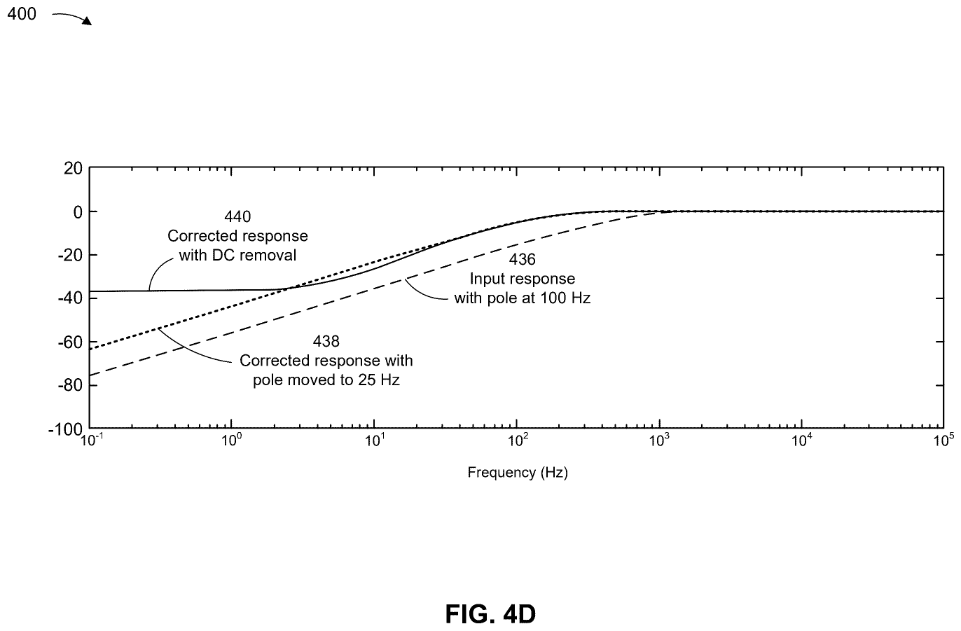

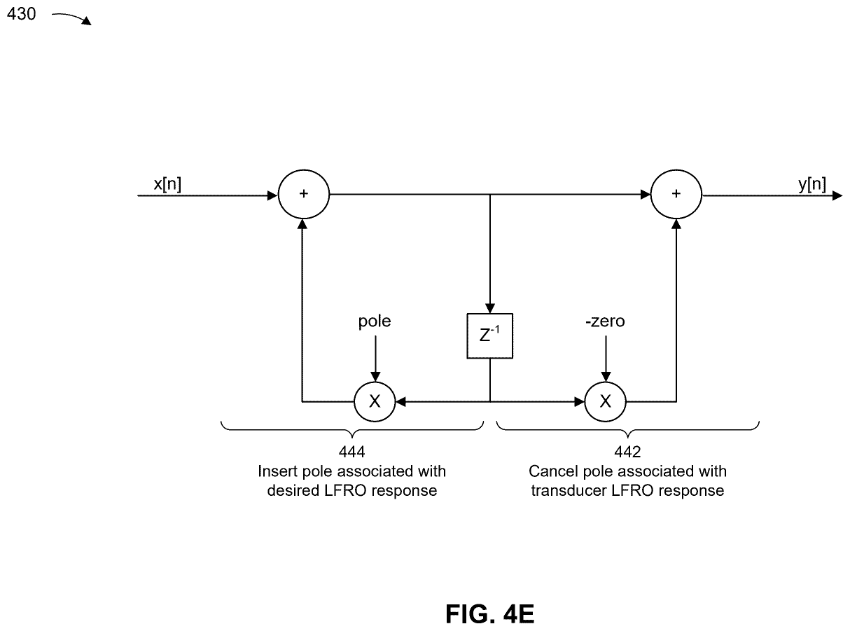

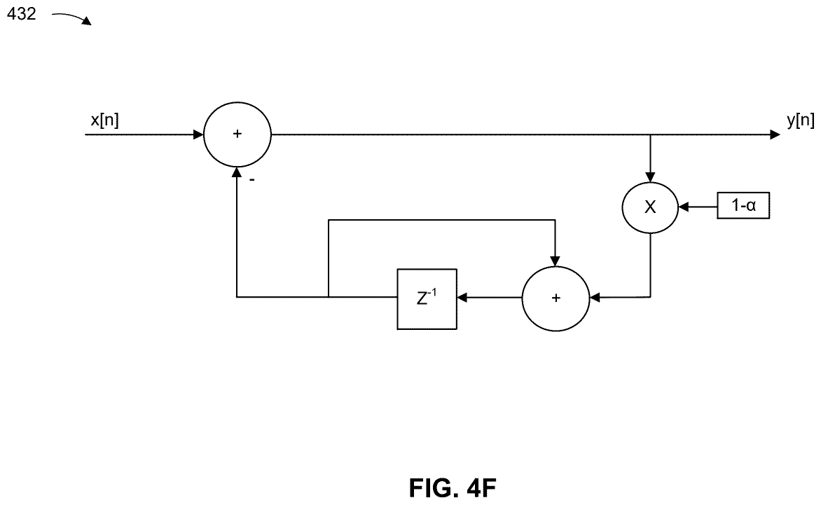

FIGS. 4A-4F are diagrams illustrating examples 400 associated with controlling or correcting an LFRO point of a signal generated by a transducer, such as a MEMS acoustic transducer, in accordance with the present disclosure. As shown in FIG. 4A, an LFRO point may be corrected or controlled in a system that includes a transducer 402, an analog-to-digital converter (ADC) 404, and an open loop correction circuit 406.

As shown in FIG. 4A, the transducer 402 may receive an incident signal 408, and may generate an analog signal 410 as a function of the incident signal 408. For example, in some aspects, the transducer 402 may be a MEMS microphone (e.g., a piezoelectric MEMS microphone), in which case the incident signal 408 may include acoustic energy or acoustic pressure and the analog signal 410 may be an electrical signal that represents the acoustic energy or acoustic pressure. However, as described herein, the transducer 402 may generally correspond to any suitable device that can convert an incident signal 408 corresponding to energy in a first form to an analog signal 410 corresponding to energy in a second form. For example, in some aspects, the transducer 402 may correspond to a MEMS transducer, an inertial sensor, a pressure sensor, a tilt sensor, a speaker, a chemical sensor, an ultrasonic transducer, and/or a condenser and/or capacitive microphone, among other examples.

As further shown in FIG. 4A, the analog signal 410 generated by the transducer 402 may exhibit a frequency response 412, which may be represented as a high pass filter response,

$$\frac{s}{s + {ω}_{c}} ,$$

where s is a complex frequency variable in an s-domain or s-plane (e.g., a Laplace variable, where s=jω, j is an imaginary number (\sqrt{−1}, ω=2πf, and f is a frequency). Furthermore, in the high pass filter response,

$$\frac{s}{s + {ω}_{c}} , s + {ω}_{c}$$

is a pore associated with the frequency response 412 of the transducer 402, and ω_{c}=2πf_{c}, where f_{c} is a cutoff frequency corresponding to the intrinsic LFRO point (or 3 dB corner) associated with the transducer 402. In some aspects, as described herein, f_{c} may generally have a value that is measured or otherwise obtained after manufacturing and/or during production testing of the transducer 402, and in some cases, the value of f_{c} may deviate from a desired LFRO point for the output of the transducer 402 (e.g., the value of f_{c} for different transducers 402 may vary in a range from about 20-200 Hz, but the desired LFRO point may be fixed for a given application of the transducer 402).

Accordingly, as described herein, the open loop correction circuit 406 may be configured to cancel the pole in the frequency response 412 associated with the analog signal 410 output by the transducer 402, s+ω_{c}, with a zero and to replace the cancelled pole with a corrected pole, s+ω_{c-new}, where ω_{c-new}=2πf_{c-new} and f_{c-new} is a cutoff frequency corresponding to the desired LFRO point or 3 dB corner (e.g., 20 Hz, 25 Hz, or another value). For example, as described herein, a “pole” generally refers to a value for a complex variable that results in a transfer function becoming infinite or undefined (e.g., a pole p is a value of s that results in division by a zero value when s−p is substituted into a transfer function, such as by causing a denominator of the transfer function to have a zero value). In contrast, as described herein, a “zero” (which differs from a zero value) generally refers to a value for a complex variable that results in the output from a transfer function being zero (e.g., a zero z is a value of s that results in a transfer function having a zero value when s−z is substituted into the transfer function, such as by causing a numerator of the transfer function to have a zero value).

Accordingly, to cancel out the pole, s+ω_{c}, in the frequency response 412 of the analog signal 410 generated by the transducer 402 with a zero and replace the cancelled pole with the corrected pole, s+ω_{c-new}, a transfer function in the s-domain or s-plane may be defined as follows:

$$H ( s ) = \frac{s + {ω}_{c}}{s + {ω}_{c - new}}$$

such that a product of the high pass filter response,

$$\frac{s}{s + {ω}_{c}} ,$$

and the transfer function H(s) is

$$\frac{s}{s + {ω}_{c - new}} .$$

In this way, applying the transfer function H(s) to the frequency response 412 would move the pole of the frequency response 412 from f_{c} (the intrinsic LFRO point associated with the transducer 402) to f_{c-new} (the desired LFRO point). However, as described herein, the open loop correction circuit 406 may be configured to move the pole of the frequency response 412 from f_{c} to f_{c-new} using digital circuitry, which may use less silicon area and provide greater accuracy than an analog correction circuit. Accordingly, as shown in FIG. 4A and described herein, the ADC 404 may be provided in a physical and/or logical path between the transducer 402 and the open loop correction circuit 406 to convert the analog signal 410 output from the transducer 402 to an input signal 414 that represents the analog signal 410 (e.g., in a digital domain). Accordingly, as described herein, the open loop correction circuit 406 may receive the input signal 414 that represents the analog signal 410 from the ADC 404, and may correct the LFRO point of the input signal 414 in a digital domain using digital circuitry. However, it will be appreciated that other suitable circuitry components may be used to create one or more zeroes and/or one or more poles to correct the LFRO point of the input signal 414 in an analog domain.

For example, as shown in FIG. 4A, and by reference number 416, the open loop correction circuit 406 may apply a transfer function to move the pole associated with the input signal 414 representing the analog signal 410 to a desired frequency. For example, the open loop correction circuit 406 may receive a first input 418 indicating the measured f_{c} value associated with the transducer 402 and a second input 420 indicating a programmed f_{c-new} value corresponding to a desired LFRO or −3 dB point for the output of the transducer 402. Accordingly, an LFRO correction function 422 to cancel the pole in the input signal 414 with a zero and replace the cancelled pole with a new pole corresponding to the desired LFRO or −3 dB point may be similar to the transfer function H(s) described above, and may be represented in a digital domain (e.g., a z-domain or z-plane, also known as a Fourier domain), as follows:

$$H ( z ) = \frac{z + ( 2 π * \frac{{f}_{c}}{{f}_{s}} - 1 )}{z + ( 2 π * \frac{{f}_{c - new}}{{f}_{s}} - 1 )}$$

where z=e^{jω} and fₛ is a sampling frequency. For example, in some aspects, f_{c} may have a value in a range from 20-200 Hz, f_{c-new} may have a value in a range from 20-40 Hz, and fₛ may have a value in a range from 300 kilohertz (kHz) to 4 megahertz (MHz), although other suitable ranges may be used for f_{c}, f_{c-new}, and fₛ.

Accordingly, as described herein, the input signal 414 that is received by the open loop correction circuit 406 has a pole at f_{c}, corresponding to the intrinsic LFRO or −3 dB point associated with the transducer 402, the zero that cancels the pole at f_{c} may be given by

$$1 - 2 π * \frac{{f}_{c}}{{f}_{s}} ,$$

and the corrected pole in a corrected frequency response 424 output by the open loop correction circuit 406 may be given by

$$1 - 2 π * \frac{{f}_{c - new}}{{f}_{s}} .$$

In this way, the open loop correction circuit 406 may apply the transfer function H(z) to the input signal 414 received from the ADC 404 to generate an output signal with the corrected frequency response 424, where the pole is moved from the intrinsic LFRO point of the transducer 402, f_{c}, to the desired LFRO or −3 dB point, f_{c-new}. For example, referring to FIG. 4B, curve 426 depicts an example frequency response for the input signal 414 that is input to the open loop correction circuit 406 (e.g., with an initial pole at f_{c}=100 Hz), and curve 428 depicts an example corrected frequency response for the output signal generated by the open loop correction circuit 406 after the transfer function H(z) is applied (e.g., with a corrected pole at f_{c-corr}=20 Hz). In FIG. 4B, the horizontal axis corresponds to a frequency in radians per second (e.g., ω=2πf) and the vertical axis represents an output power magnitude (in dB).

In some aspects, as shown in FIG. 4C, the input signal 414 input to the open loop correction circuit 406 may be denoted x[z] and the output from the open loop correction circuit 406 may be denoted Y[z], whereby a relationship between the input and the output of the open loop correction circuit 406 may be as follows:

Y[z]=Y[z]*z⁻¹*pole+x[z]−x[z]*zero*z⁻¹

where

$$zero = 1 - 2 π * \frac{{f}_{c}}{{f}_{s}}$$

and

$$pole = 1 - 2 π * \frac{{f}_{c - new}}{{f}_{s}} .$$

However, in some cases, a direct current (DC) offset may be present in x[z], which may pose challenges due to the LFRO correction function 422 having a high gain at low frequencies. For example, in cases where f_{c}>f_{c-new} (e.g., the LFRO correction function 422 moves the pole to a lower frequency), the DC offset may experience a gain up to 5×, or 14 dB. Accordingly, as shown in FIG. 4C, the open loop correction circuit 406 may include an LFRO correction component 430 that implements the LFRO correction function 422, and the open loop correction circuit 406 may further include a DC removal component 432 that implements a DC offset removal function 434 to remove the DC offset prior to the LFRO correction component 430 applying the LFRO correction function 422. For example, in some aspects, the DC offset removal function 434 may be as follows:

$${H}_{DC} ( z ) = \frac{1 - {z}^{- 1}}{1 - α * {z}^{- 1}}$$

where α is a constant with a configurable value (e.g.,

$$α = 1 - \frac{1}{{2}^{18}}$$

to place a −3 dB corner at 2.5 Hz at a 4 MHz sampling frequency).

For example, referring to FIG. 4D, curve 436 depicts an example frequency response at the input to the open loop correction circuit 406 (e.g., with an initial pole at f_{c}=100 Hz), curve 438 depicts an example corrected frequency response at the output of the open loop correction circuit 406 in cases where the LFRO correction function 422 is applied (e.g., with a corrected pole at f_{c-new}=25 Hz) without first applying the DC offset removal function 434, and curve 440 depicts an example corrected frequency response at the output of the open loop correction circuit 406 in cases where the DC offset removal function 434 is applied before the LFRO correction function 422.

In some aspects, as described herein, the open loop correction circuit 406 may be implemented using digital circuitry to save silicon area and improve accuracy relative to an analog approach. For example, in some aspects, FIG. 4E illustrates one possible implementation for the LFRO correction component 430 that implements the LFRO correction function 422, where the LFRO correction component 430 includes a first set of components 442 that are configured to cancel the pole associated with an input frequency response with a zero, and a second set of components 444 that are configured to replace the cancelled pole with a corrected pole at the desired frequency. Furthermore, FIG. 4F illustrates an implementation for the DC removal component 432 that implements the DC offset removal function 434. In some aspects, in the example implementation shown in FIG. 4F, the input and the output of the DC removal component 432 are shown by x[n] and y[n], respectively, a block that generates a 1−α value may be implemented using a multiplier, and remaining components of the DC removal component 432 may include an adder and a register. However, other possible digital and/or analog circuits may be configured to implement the LFRO correction function 422 and/or the DC offset removal function 434.

As indicated above, FIGS. 4A-4F are provided as examples. Other examples may differ from what is described with respect to FIGS. 4A-4F.

In some aspects, as described herein, an apparatus may include means for generating an analog signal as a function of an incident signal; means for generating an input signal that represents the analog signal, wherein the input signal is associated with a first frequency response with a pole at a first frequency; and/or means for applying a transfer function to the input signal to generate an output signal, wherein the output signal is associated with a second frequency response in which the pole is moved to a second frequency. In some aspects, the means for the apparatus to perform processes, operations, and/or functions described herein may include one or more components of the MEMS device 100 described in connection with FIG. 1, such as the MEMS chip 112, the piezoelectric structure 114, the ASIC chip 116, the bond wire 118, and/or the acoustic port 124. Additionally, or alternatively, the means for the apparatus to perform processes, operations, and/or functions described herein may include one or more components of the MEMS device die described in connection with FIGS. 2A-2B, such as the cantilevers 230, the piezoelectric layers 234, and/or the sensing electrodes 236/238. Additionally, or alternatively, the means for the apparatus to perform processes, operations, and/or functions described herein may include one or more components of the transducer system described in connection with FIGS. 4A-4F, such as the transducer 402, the ADC 404, and/or the open loop correction circuit 406.

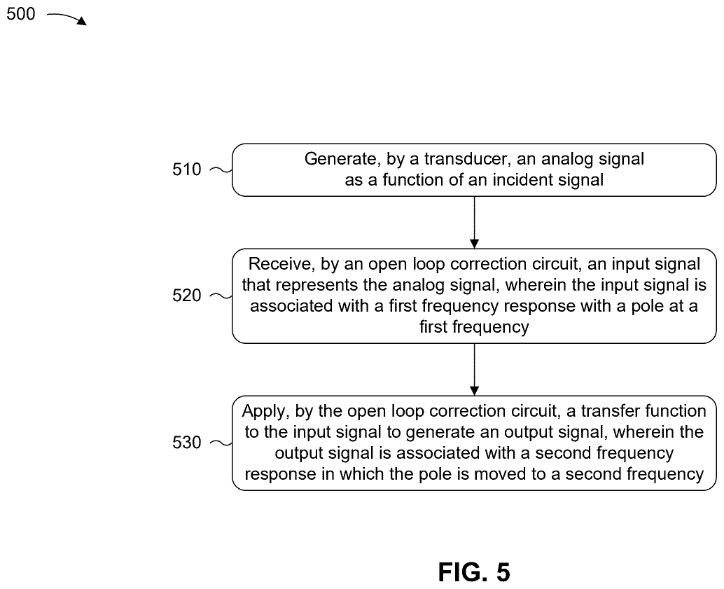

FIG. 5 is a flowchart of an example process 500 associated with controlling or correcting an LFRO point of a signal generated by a transducer, such as a MEMS acoustic transducer. In some implementations, one or more process blocks of FIG. 5 are performed by an open loop correction circuit (e.g., open loop correction circuit 406). In some implementations, one or more process blocks of FIG. 5 are performed by another device or a group of devices separate from or including the open loop correction circuit, such as a transducer (e.g., transducer 402) and/or an ADC (e.g., ADC 404).

As shown in FIG. 5, process 500 may include generating an analog signal as a function of an incident signal (block 510). For example, the transducer may generate an analog signal as a function of an incident signal, as described above.

As further shown in FIG. 5, process 500 may include receiving an input signal that represents the analog signal, wherein the input signal is associated with a first frequency response with a pole at a first frequency (block 520). For example, the open loop correction circuit may receive an input signal that represents the analog signal, wherein the input signal is associated with a first frequency response with a pole at a first frequency, as described above.

As further shown in FIG. 5, process 500 may include applying a transfer function to the input signal to generate an output signal, wherein the output signal is associated with a second frequency response in which the pole is moved to a second frequency (block 530). For example, the open loop correction circuit may apply a transfer function to the input signal to generate an output signal, wherein the output signal is associated with a second frequency response in which the pole is moved to a second frequency, as described above.

Process 500 may include additional implementations, such as any single implementation or any combination of implementations described below and/or in connection with one or more other processes described elsewhere herein.

In a first implementation, applying the transfer function includes canceling the pole associated with the first frequency response with a zero, and replacing the cancelled pole with a corrected pole that moves the pole to the second frequency.

In a second implementation, alone or in combination with the first implementation, the zero is a function of the first frequency and a sampling frequency, and the corrected pole is a function of the second frequency and the sampling frequency.

In a third implementation, alone or in combination with one or more of the first and second implementations, process 500 includes receiving, by an ADC, the analog signal from the transducer, and converting, by the ADC converter, the analog signal to the input signal that digitally represents the analog signal.

In a fourth implementation, alone or in combination with one or more of the first through third implementations, process 500 includes removing a direct current offset from the input signal before applying the transfer function to the input signal.

In a fifth implementation, alone or in combination with one or more of the first through fourth implementations, the first frequency is an LFRO point associated with the transducer.

In a sixth implementation, alone or in combination with one or more of the first through fifth implementations, the second frequency is a programmed value.

In a seventh implementation, alone or in combination with one or more of the first through sixth implementations, the first frequency is within a first range, and the second frequency is within a second range that is narrower than the first range and overlapping with the first range.

In an eighth implementation, alone or in combination with one or more of the first through seventh implementations, the transducer is a MEMS acoustic transducer.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The following provides an overview of some Aspects of the present disclosure:

Aspect 1: A system, comprising: a transducer configured to receive an incident signal and to generate an analog signal as a function of the incident signal; and an open loop correction circuit configured to: receive an input signal that represents the analog signal, wherein the input signal is associated with a first frequency response with a pole at a first frequency; and apply a transfer function to the input signal to generate an output signal, wherein the output signal is associated with a second frequency response in which the pole is moved to a second frequency.

Aspect 2: The system of Aspect 1, wherein the transfer function cancels the pole associated with the first frequency response with a zero and replaces the cancelled pole with a corrected pole to move the pole to the second frequency.

Aspect 3: The system of Aspect 2, wherein the zero is a function of the first frequency and a sampling frequency, and wherein the corrected pole is a function of the second frequency and the sampling frequency.

Aspect 4: The system of any of Aspects 1-3, further comprising: an ADC configured to receive the analog signal from the transducer and to convert the analog signal to the input signal that digitally represents the analog signal.

Aspect 5: The system of any of Aspects 1-4, wherein the open loop correction circuit is further configured to: remove a direct current offset from the input signal before the transfer function is applied to the input signal.

Aspect 6: The system of any of Aspects 1-5, wherein the first frequency is an LFRO point associated with the transducer.

Aspect 7: The system of any of Aspects 1-6, wherein the second frequency is a programmed value.

Aspect 8: The system of any of Aspects 1-7, wherein the first frequency is within a first range, and wherein the second frequency is within a second range that is narrower than the first range and overlapping with the first range.

Aspect 9: The system of any of Aspects 1-8, wherein the transducer is a MEMS acoustic transducer.

Aspect 10: A method, comprising: generating, by a transducer, an analog signal as a function of an incident signal; receiving, by an open loop correction circuit, an input signal that represents the analog signal, wherein the input signal is associated with a first frequency response with a pole at a first frequency; and applying, by the open loop correction circuit, a transfer function to the input signal to generate an output signal, wherein the output signal is associated with a second frequency response in which the pole is moved to a second frequency.

Aspect 11: The method of Aspect 10, wherein applying the transfer function includes: cancelling the pole associated with the first frequency response with a zero; and replacing the cancelled pole with a corrected pole that moves the pole to the second frequency.

Aspect 12: The method of Aspect 11, wherein the zero is a function of the first frequency and a sampling frequency, and wherein the corrected pole is a function of the second frequency and the sampling frequency.

Aspect 13: The method of any of Aspects 10-12, further comprising: receiving, by an ADC, the analog signal from the transducer; and converting, by the ADC converter, the analog signal to the input signal that digitally represents the analog signal.

Aspect 14: The method of any of Aspects 10-13, further comprising: removing a direct current offset from the input signal before applying the transfer function to the input signal.

Aspect 15: The method of any of Aspects 10-14, wherein the first frequency is an LFRO point associated with the transducer.

Aspect 16: The method of any of Aspects 10-15, wherein the second frequency is a programmed value.

Aspect 17: The method of any of Aspects 10-16, wherein the first frequency is within a first range, and wherein the second frequency is within a second range that is narrower than the first range and overlapping with the first range.

Aspect 18: The method of any of Aspects 10-17, wherein the transducer is a MEMS acoustic transducer.

Aspect 19: An apparatus, comprising: means for generating an analog signal as a function of an incident signal; means for generating an input signal that represents the analog signal, wherein the input signal is associated with a first frequency response with a pole at a first frequency; and means for applying a transfer function to the input signal to generate an output signal, wherein the output signal is associated with a second frequency response in which the pole is moved to a second frequency.

Aspect 20: The apparatus of Aspect 19, further comprising: means for removing a direct current offset from the input signal before the transfer function is applied to the input signal.

Aspect 21: A system configured to perform one or more operations recited in one or more of Aspects 1-20.

Aspect 22: A device configured to perform one or more operations recited in one or more of Aspects 1-20.

Aspect 23: A circuit configured to perform one or more operations recited in one or more of Aspects 1-20.

Aspect 22: An apparatus comprising means for performing one or more operations recited in one or more of Aspects 1-20.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A system, comprising:
a transducer configured to receive an incident signal and to generate an analog signal as a function of the incident signal; and
an open loop correction circuit configured to:
receive an input signal that represents the analog signal, wherein the input signal is associated with a first frequency response with a pole at a first frequency; and
apply a transfer function to the input signal to generate an output signal, wherein the output signal is associated with a second frequency response in which the pole is moved to a second frequency.

2. The system of claim 1, wherein the transfer function cancels the pole associated with the first frequency response with a zero and replaces the cancelled pole with a corrected pole to move the pole to the second frequency.

3. The system of claim 2, wherein the zero is a function of the first frequency and a sampling frequency, and wherein the corrected pole is a function of the second frequency and the sampling frequency.

4. The system of claim 1, further comprising:
an analog-to-digital converter (ADC) configured to receive the analog signal from the transducer and to convert the analog signal to the input signal that digitally represents the analog signal.

5. The system of claim 1, wherein the open loop correction circuit is further configured to:
remove a direct current offset from the input signal before the transfer function is applied to the input signal.

6. The system of claim 1, wherein the first frequency is a low frequency roll off (LFRO) point associated with the transducer.

7. The system of claim 1, wherein the second frequency is a programmed value.

8. The system of claim 1, wherein the first frequency is within a first range, and wherein the second frequency is within a second range that is narrower than the first range and overlapping with the first range.

9. The system of claim 1, wherein the transducer is a micro-electro-mechanical systems (MEMS) acoustic transducer.

10. A method, comprising:
generating, by a transducer, an analog signal as a function of an incident signal;
receiving, by an open loop correction circuit, an input signal that represents the analog signal, wherein the input signal is associated with a first frequency response with a pole at a first frequency; and
applying, by the open loop correction circuit, a transfer function to the input signal to generate an output signal, wherein the output signal is associated with a second frequency response in which the pole is moved to a second frequency.

11. The method of claim 10, wherein applying the transfer function includes:
cancelling the pole associated with the first frequency response with a zero; and
replacing the cancelled pole with a corrected pole that moves the pole to the second frequency.

12. The method of claim 11, wherein the zero is a function of the first frequency and a sampling frequency, and wherein the corrected pole is a function of the second frequency and the sampling frequency.

13. The method of claim 10, further comprising:
receiving, by an analog-to-digital converter (ADC), the analog signal from the transducer; and
converting, by the ADC converter, the analog signal to the input signal that digitally represents the analog signal.

14. The method of claim 10, further comprising:
removing a direct current offset from the input signal before applying the transfer function to the input signal.

15. The method of claim 10, wherein the first frequency is a low frequency roll off (LFRO) point associated with the transducer.

16. The method of claim 10, wherein the second frequency is a programmed value.

17. The method of claim 10, wherein the first frequency is within a first range, and wherein the second frequency is within a second range that is narrower than the first range and overlapping with the first range.

18. The method of claim 10, wherein the transducer is a micro-electro-mechanical systems (MEMS) acoustic transducer.

19. An apparatus, comprising:
means for generating an analog signal as a function of an incident signal;
means for generating an input signal that represents the analog signal, wherein the input signal is associated with a first frequency response with a pole at a first frequency; and
means for applying a transfer function to the input signal to generate an output signal, wherein the output signal is associated with a second frequency response in which the pole is moved to a second frequency.

20. The apparatus of claim 19, further comprising:
means for removing a direct current offset from the input signal before the transfer function is applied to the input signal.
